(19) United States
(12) Patent Application Publication
(10) Pub. No.: US 2013/0168754 A1
(43) Pub. Date: Jul. 4, 2013

(54) METHOD FOR FABRICATING A SEMICONDUCTOR DEVICE WITH INCREASED RELIABILITY

(71) Applicants: Jeng Hwa Liao, Hsinchu City (TW); Jung Yu Shieh, Hsinchu City (TW); Ling Wuu Yang, Hsinchu City (TW)

(72) Inventors: Jeng Hwa Liao, Hsinchu City (TW); Jung Yu Shieh, Hsinchu City (TW); Ling Wuu Yang, Hsinchu City (TW)

(73) Assignee: MACRONIX INTERNATIONAL CO., LTD., Hsin-chu (TW)

(21) Appl. No.: 13/338,744

(22) Filed: Dec. 28, 2011

(51) Int. Cl. H01L 29/788; H01L 21/28

(52) U.S. Cl. 257/315; 438/591; 257/E21.19; 257/E29.3

(57) ABSTRACT

A method of forming a semiconductor device is provided. The method includes providing a semiconductor substrate, and forming a first conductive layer over the substrate. In one example, an insulating layer may be formed over the semiconductor substrate, with the first conductive layer being formed over the insulating layer. The method also includes forming an interpoly dielectric layer over the first conductive layer. In this regard, forming the interpoly dielectric layer includes forming a silicon oxide layer, and subjecting the silicon oxide layer to oxide densification to form an oxide-densified silicon oxide layer. And the method includes forming a second conductive layer over the interpoly dielectric layer.

### FIELD

Example embodiments generally relate to memory device fabrication, and more particularly, relate to memory device fabrication including oxide densification of an interpoly dielectric layer for increased reliability.

### BACKGROUND

Nonvolatile memory devices, such as EPROM, EEPROM and flash EPROM (e.g., NAND/NOR type flash memory) devices, are well known in the art. In general, nonvolatile memory devices comprise a series of transistors which act as memory cells. Each transistor includes source and drain regions formed on the surface of a n- or p-type semiconductor substrate, an insulating layer formed on the surface of the semiconductor substrate positioned between the source and drain regions, a floating gate positioned on the insulating layer for holding a charge, a layer of an insulating dielectric formed on the floating gate for insulating the floating gate, thereby enabling the floating gate to retain its charge and a control gate positioned on the insulating dielectric layer. In the case where both the floating gate and the control gate are made of polysilicon, the insulating dielectric between the respective layers is sometimes called an interpoly dielectric. The interpoly dielectric need not be strictly an oxide (e.g., silicon oxide); often it is made of an oxide-nitride-oxide (ONO) composite.

A bit of binary data is stored in the floating gate of each memory cell as either a high or low level charge, a high level charge corresponding to a first data value (e.g., 1), a low level charge corresponding to a second data value (e.g., 0). Since the value of the data stored in the floating gate is a function of the size of the charge stored in the floating gate, charge loss or gain by the floating gate can alter the value of the data stored in the memory cell. It is therefore essential to the functioning of a nonvolatile memory device that each floating gate be capable of long term charge retention.

The ability of a floating gate to retain a charge is primarily determined by the interpoly dielectric used to insulate the floating gate. In order to prevent charge loss, the dielectric must have a high break down voltage. For example, when a high potential is applied to the control gate during programming, the dielectric must have a sufficiently high breakdown voltage to block electrons from the floating gate to the control gate.

Once a charge is introduced into the floating gate, the dielectric must also be able to prevent charge leakage from the floating gate. Charge leakage generally occurs through defects in the dielectric layer. It is therefore very important for the interpoly dielectric to have a high degree of structural integrity which is generally associated with a low concentration of pinholes.

Charges are transferred to a floating gate by a variety of methods, such as avalanche injection, channel injection and Fowler-Nordheim tunneling. It is generally desirable for a memory device to have a high gate coupling ratio (GCR) between the floating gate and the control gate. The gate coupling ratio is a function of the capacitance between the floating gate and the control gate and hence is related to the thickness of the dielectric layer. In order to maximize the gate coupling ratio, as well as to minimize the amount of heat generated by the device, it is desirable to minimize the thickness of the interpoly dielectric layer. However, as the thickness of the dielectric is reduced such as in the case of a thinned-down interpoly dielectric, charge leakage through defects in the dielectric generally increases.

### SUMMARY

In light of the foregoing background, exemplary embodiments of the present disclosure provide a method of fabricating a memory device including oxide densification of an insulating dielectric layer (e.g., interpoly dielectric layer) between a floating gate and a control gate for increased reliability. The method of exemplary embodiments may improve quality of the dielectric layer without increasing its physical and electrical thickness. In one example, the oxide densification may be accomplished by plasma oxidation, which may be performed at a relatively low temperature, thereby meeting lower thermal budget requirements as the device is scaled down. It may allow the continued dielectric scaling to meet a gate coupling ratio requirement without sacrificing device reliability.

According to one example aspect of the present disclosure, a method of forming a semiconductor device is provided. The method of this example aspect includes providing a semiconductor substrate, and forming a first conductive layer over the substrate. The method also includes forming an interpoly dielectric layer over the first conductive layer. In this regard, forming the interpoly dielectric layer includes forming an oxide-densified silicon oxide layer and forming a second conductive layer over the interpoly dielectric layer.

In one example, forming the oxide-densified silicon oxide layer may include forming a silicon oxide layer and subjecting the silicon oxide layer to oxide densification to form an oxide-densified silicon oxide layer.

In one example, the silicon oxide layer is formed by low-pressure chemical vapor deposition or atomic layer deposition, or formed of a radical oxide.

In one example, subjecting the silicon oxide layer to oxide densification comprises subjecting the silicon oxide layer to plasma oxidation, such as by using a radio frequency or microwave source. In one example, the silicon oxide layer is subjected to plasma oxidation at a temperature at or below 700° Celsius. The oxide-densified silicon oxide layer in one example has a thickness between approximately 15 Å and 50 Å.

In one example, an insulating layer may be formed over the semiconductor substrate, with the first conductive layer being formed over the insulating layer.

In one example, the silicon oxide layer is a first silicon oxide layer, and the oxide-densified silicon oxide layer is a first oxide-densified silicon oxide layer. In this example, forming the interpoly dielectric layer may further include forming a second silicon oxide layer over the first oxide-densified silicon oxide layer, and subjecting the second silicon oxide layer to oxide densification to form a second oxide-densified silicon oxide layer. Even further, forming the interpoly dielectric layer may include forming a silicon nitride layer over the first oxide-densified silicon oxide layer, with the second silicon oxide layer being formed over the silicon nitride layer. In various examples, the first oxide-densified silicon oxide layer may have a thickness between approximately 15 Å and 50 Å, and the second oxide-densified silicon oxide layer may have a thickness between approximately 30 Å and 80 Å.

These and other processes, features, and characteristics of these and other embodiments, including method and semiconductor device embodiments, of the present invention, as well as additional details thereof, are further described herein.

### BRIEF DESCRIPTION OF THE DRAWINGS

Having thus described the disclosure in general terms, reference will now be made to the accompanying drawings, which are not necessarily drawn to scale, and wherein:

FIGS. 1a-1g, which are schematic diagrams in cross-sectional view illustrating a method of fabricating a semiconductor device according to one example embodiment of the present disclosure;

FIG. 2 is a graph comparatively illustrating the equivalent oxide thickness (EOT) of various interpoly dielectric layer structures two of which include plasma oxidation according to example embodiments of the present disclosure; and

FIGS. 3 and 4 are graphs comparatively illustrating retention performance and endurance performance, respectively, two interpoly dielectric layer structures one of which includes plasma oxidation according to example embodiments of the present disclosure.

### DETAILED DESCRIPTION

Exemplary embodiments now will be described more fully hereinafter with reference to the accompanying drawings. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

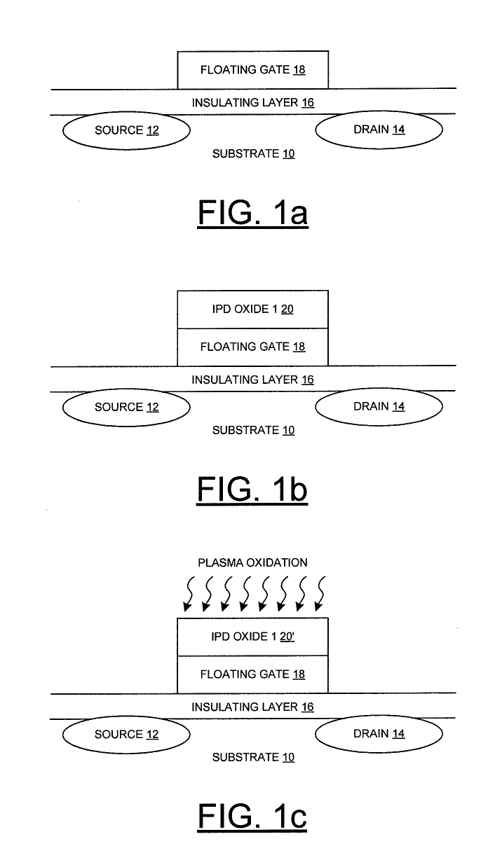

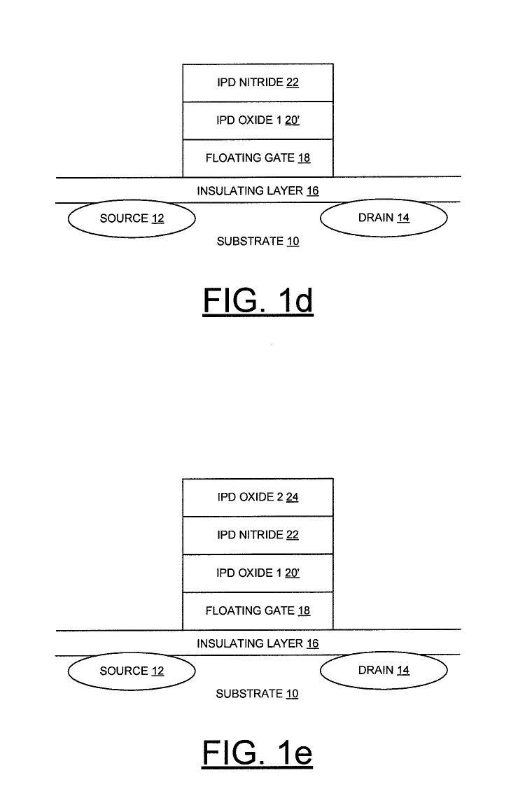

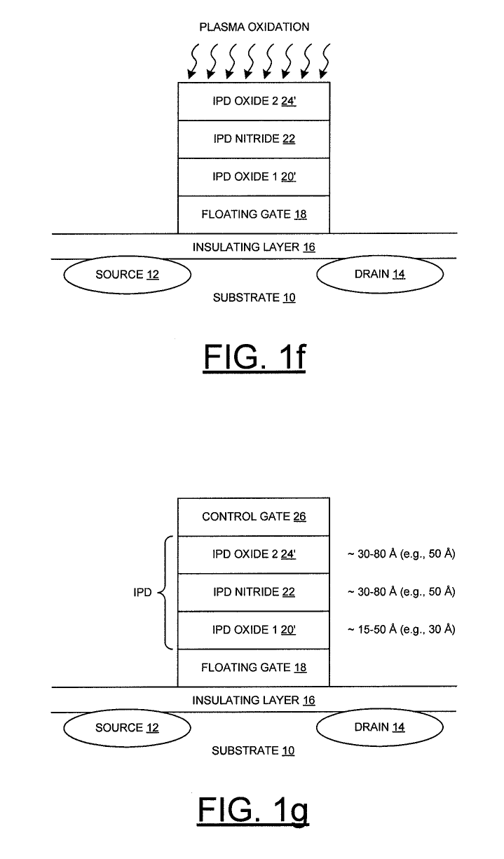

Reference is made to FIGS. 1a-1g, which are schematic diagrams in cross-sectional view illustrating a method of fabricating a semiconductor device according to one example embodiment of the present disclosure (“example,” “exemplary” and like terms as used herein refer to “serving as an example, instance or illustration”). The semiconductor device of one example may be a non-volatile memory device, such as an EPROM, EEPROM, flash EPROM (e.g., NAND/NOR type flash memory), charge-trapping memory, embedded-memory or the like. It should be understood, however, that the semiconductor memory device may be another type of device with a thermal budget and electrical thickness concerns that may be addressed by oxide densification of one or more layers of the device.

As shown in FIG. 1a, an n- or p-type semiconductor substrate 10 is provided for forming one or more active devices. In instances in which the semiconductor device being formed is a non-volatile memory device, diffused regions may be formed in the substrate. In various examples, the diffused regions may be n- or p-type diffused regions depending on the type of substrate. As shown, for example, the diffused regions may function as a source 12 and a drain 14.

An insulating layer 16 such as a tunnel oxide layer is formed or deposited over the substrate 10. A first conductive layer is formed over the tunnel oxide, and may function as a floating gate 18. In this embodiment, the first conductive layer is a polysilicon layer. A layer of an insulating dielectric may be formed on the floating gate for insulating the floating gate. The insulating dielectric may be referred to as an interpoly dielectric (IPD) and may be formed of or otherwise include a silicon oxide. In one example embodiment, the interpoly dielectric may be made of an oxide-nitride-oxide (ONO) composite. In this example, the interpoly dielectric may include a first silicon oxide layer 20 formed over the floating gate, as shown in FIG. 1b.

The first silicon oxide layer 20 may be formed in any of a number of different manners. For example, the first silicon oxide layer may be formed by low-pressure chemical vapor deposition (LPCVD) such as in the context of oxide deposited using tetra ethyl ortho silicate (TEOS), high-temperature deposited oxide (HTO) or the like. In other examples, the first silicon oxide layer may be formed by in-situ steam generation (ISSG), atomic layer deposition (ALD) or the like. And in one example, the first silicon oxide layer may be formed of a radical oxide.

As shown in FIG. 1c, the first silicon oxide layer 20 may be subject to oxide densification to form a first oxide-densified silicon oxide layer 20′. In one example, the oxide densification may be accomplished by plasma oxidation. In one example, the plasma oxidation may be performed using a radio frequency (RF) or microwave source, and may be performed at a relatively low temperature. The plasma oxidation may be performed at a relatively low temperature such as at or below 700° Celsius (C), thereby meeting lower thermal budget requirements as the device is scaled down. Also, after plasma oxidation, the oxygen to silicon (O/Si) ratio may be enhanced such as from 1.5 to 2.5 due to more oxygen being incorporated into the first silicon oxide layer. A ratio greater than 2 is preferred in this embodiment. A oxygen to silicon (O/Si) ratio of 1.5 to 2.5, such as greater than 2 in this embodiment, may thereby improve the quality of the first silicon oxide layer.

Also as part of the interpoly dielectric, a silicon nitride layer 22 may be formed over the first oxide-densified silicon oxide layer 20′, as shown in FIG. 1d; and a second silicon oxide layer 24 may be formed over the silicon nitride layer, and shown in FIG. 1e. Similar to the first silicon oxide layer 20, the second silicon oxide layer may be a LPCVD oxide (e.g., TEOS, HTO), ISSG oxide, ALD oxide, radical oxide or the like. Also similar to the first silicon oxide layer, the second silicon oxide layer may be subject to oxide densification to form a second oxide-densified silicon oxide layer 24′, as shown in FIG. 1f. Even further, in one example, the oxide densification may be accomplished by plasma oxidation using a RF or microwave source, and at a relatively low temperature (e.g., at or below 700° C.). A second conductive layer, such as where the second conductive layer is a polysilicon layer, may then be formed over the interpoly dielectric, or rather the second oxide-densified silicon oxide layer, and may function as a control gate 26, as shown in FIG. 1g.

As shown in FIG. 1g, in one example, the first oxide-densified silicon oxide layer 20′ may have a thickness between approximately 15 angstroms (Å) and 50 Å, such as a thickness of approximately 30 Å. The silicon nitride layer 22 and second oxide-densified silicon oxide layer 24′ may each have a thickness between approximately 30 Å and 80 Å, such as a thickness of approximately 50 Å. Plasma oxidation thickness on bare silicon ranges from 10 Å to 100 Å based on the original oxide thickness. Different original oxide thicknesses will apply different plasma oxidation treatments to avoid increasing the original oxide thickness. For example, for thinner original oxide thickness, a plasma oxidation treatment with an oxide thickness of 10 Å on bare silicon can be applied to improve the original oxide quality without increasing the thickness.

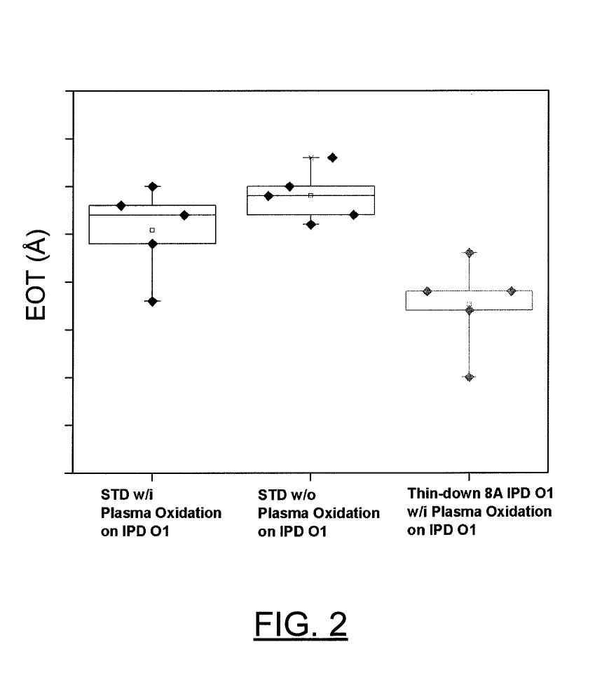

FIG. 2 is a graph comparatively illustrating the equivalent oxide thickness (EOT) of two standard (STD) interpoly dielectrics with and without plasma densification of the first silicon oxide layer 20, and a third interpoly dielectric with plasma densification of a thinned-down (8 Å) first silicon oxide layer (thinned-down interpoly dielectric). As shown, the equivalent oxide thickness is similar for the standard interpoly dielectric with and without plasma oxidation. And the thinned-down interpoly dielectric with plasma oxidation shows a smaller equivalent oxide thickness than the standard interpoly dielectric with plasma oxidation. The plasma oxidation thickness on bare silicon is 15 Å. However, the total equivalent oxide thickness is the same because the plasma oxidation treatment O1 will not increase the oxide thickness. This also applies to the standard interpoly dielectric with plasma oxidation.

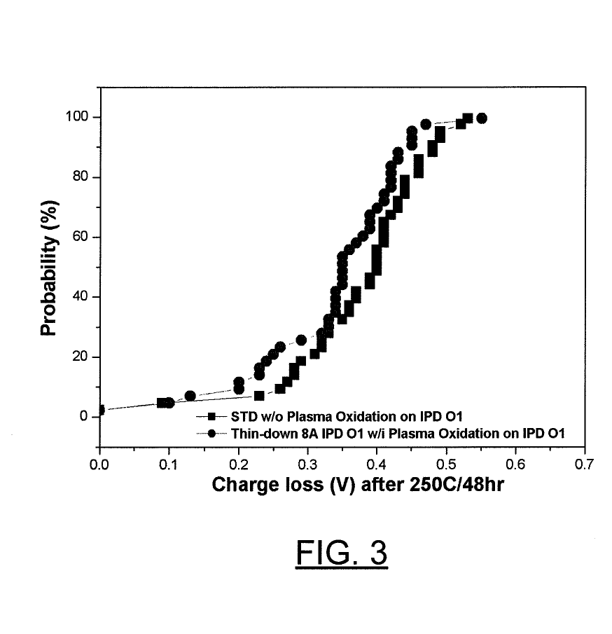

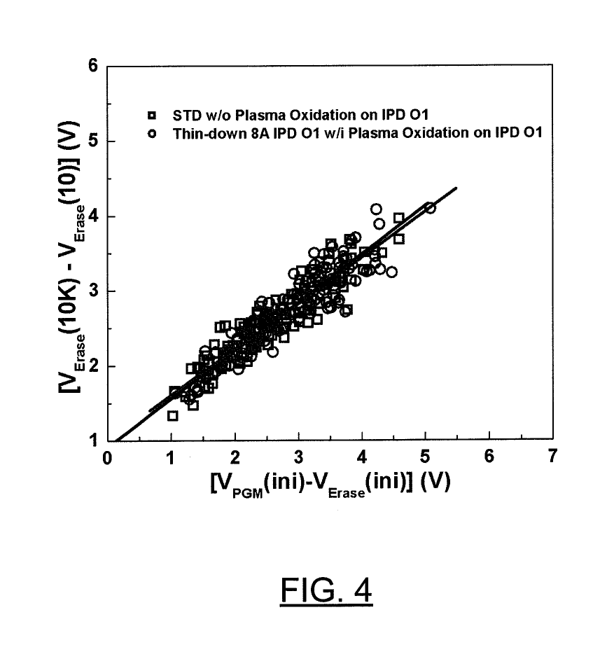

FIGS. 3 and 4 are graphs comparatively illustrating retention performance and endurance performance, respectively, for the standard interpoly dielectric without plasma oxidation and thinned-down interpoly dielectric with plasma oxidation. As shown, even for the thinned-down interpoly dielectric after plasma oxidation, both the retention performance and endurance performance is comparable to the standard interpoly dielectric without plasma oxidation.

As demonstrated, oxide densification (e.g., plasma oxidation) of one or more layers of the interpoly dielectric of a semiconductor device (e.g, memory device) may improve reliability of the device, such as its retention and endurance, without increasing the interpoly dielectrics physical and electrical thickness. The oxide densification may also allow continued interpoly dielectric scaling to meet a gate coupling ratio requirement without sacrificing the device's reliability.

Many modifications and other embodiments of the invention will come to mind to one skilled in the art to which this invention pertains having the benefit of the teachings presented in the foregoing descriptions and the associated drawings. For example, although described as a multilayer interpoly dielectric, the interpoly dielectric may instead include a single silicon oxide layer, which may be subject to oxide densification as explained above. Also for example, although both the first and second silicon oxide layers may be subject to oxide densification as explained above, in other instances, only one or the other but not both of the silicon oxide layers may be subject to oxide densification. Even further, for example, oxide densification may be applied to other one or more oxide layers of other structures improve their quality. This may include, for example, the linear oxide layer of a shallow trench isolation structure. This method can also be applied at the spacer oxide (SPR DEP OX), and shallow trench isolation (STI) liner oxide quality improves. The spacer oxide application is for word-line spacer fill-in to avid the word-line-word-line bridge. So plasma oxide treatment is applied on the spacer oxide to improve the oxide quality and reduce the word-line-word-line bridge rate. It should therefore be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method of forming a semiconductor device, the method comprising:
providing a semiconductor substrate;
forming a first conductive layer over the substrate;
forming an interpoly dielectric layer over the first conductive layer, wherein forming the interpoly dielectric layer includes forming an oxide-densified silicon oxide layer; and
forming a second conductive layer over the interpoly dielectric layer.

2. The method of claim 1, wherein the oxide-densified silicon oxide layer has an oxygen to silicon (O/Si) ratio between 1.5 to 2.5.

3. The method of claim 1, wherein forming an oxide-densified silicon oxide layer comprises:
forming a silicon oxide layer; and
subjecting the silicon oxide layer to oxide densification.

4. The method of claim 3, wherein subjecting the silicon oxide layer to oxide densification comprises subjecting the silicon oxide layer to plasma oxidation.

5. The method of claim 4, wherein the silicon oxide layer is subjected to plasma oxidation using a radio frequency or microwave source.

6. The method of claim 4, wherein the silicon oxide layer is subjected to plasma oxidation at a temperature at or below 700° Celsius.

7. The method of claim 2, wherein the silicon oxide layer is formed by low-pressure chemical vapor deposition or atomic layer deposition, or formed of a radical oxide.

8. The method of claim 1, wherein the oxide-densified silicon oxide layer has a thickness between approximately 15 Å and 50 Å.

9. The method of claim 1, further comprising forming an insulating layer over the semiconductor substrate, wherein the first conductive layer is formed over the insulating layer.

10. The method of claim 1, wherein the oxide-densified silicon oxide layer is a first oxide-densified silicon oxide layer, and wherein forming the interpoly dielectric layer further comprises:
forming a second oxide-densified silicon oxide layer over the first oxide-densified silicon oxide layer.

11. The method of claim 10, wherein forming the interpoly dielectric layer further comprises forming a silicon nitride layer over the first oxide-densified silicon oxide layer, wherein the second oxide-densified silicon oxide layer is formed over the silicon nitride layer.

12. The method of claim 10, wherein the first oxide-densified silicon oxide layer has a thickness between approximately 15 Å and 50 Å, and the second oxide-densified silicon oxide layer has a thickness between approximately 30 Å and 80 Å.

13. A semiconductor device comprising:
a semiconductor substrate;
a first conductive layer formed over the substrate;
an interpoly dielectric layer formed over the first conductive layer, wherein the interpoly dielectric layer includes an oxide-densified silicon oxide layer; and
a second conductive layer formed over the interpoly dielectric layer.

14. The semiconductor device of claim 13, wherein the oxide-densified silicon oxide layer has an oxygen to silicon (O/Si) ratio between 1.5 to 2.5.

15. The semiconductor device of claim 13, wherein the oxide-densified silicon oxide layer comprises a silicon oxide layer that has been subjected to plasma oxidation, thereby forming the oxide-densified silicon oxide layer.

16. The semiconductor device of claim 15, wherein the oxide-densified silicon oxide layer has been subjected to plasma oxidation using a radio frequency or microwave source.

17. The semiconductor device of claim 15, wherein the oxide-densified silicon oxide layer has been subjected to plasma oxidation at a temperature at or below 700° Celsius.

18. The semiconductor device of claim 15, wherein the silicon oxide layer comprises a silicon oxide layer formed by low-pressure chemical vapor deposition or atomic layer deposition, or formed of a radical oxide.

19. The semiconductor device of claim 13, wherein the oxide-densified silicon oxide layer has a thickness between approximately 15 Å and 50 Å.

20. The semiconductor device of claim 13, further comprising:
an insulating layer formed over the semiconductor substrate, the first conductive layer having been formed over the insulating layer.

21. The semiconductor device of claim 13, wherein the oxide-densified silicon oxide layer is a first oxide-densified silicon oxide layer, and wherein the interpoly dielectric layer further comprises:
a second oxide-densified silicon oxide layer formed over the first oxide-densified silicon oxide layer.

22. The semiconductor device of claim 21, wherein the interpoly dielectric layer further includes a silicon nitride layer formed over the first oxide-densified silicon oxide layer, the second oxide-densified silicon oxide layer having been formed over the silicon nitride layer.

23. The semiconductor device of claim 21, wherein the first oxide-densified silicon oxide layer has a thickness between approximately 15 Å and 50 Å, and the second oxide-densified silicon oxide layer has a thickness between approximately 30 Å and 80 Å.

24. A semiconductor device comprising:
a semiconductor substrate;
a first conductive layer formed over the substrate;
an interpoly dielectric layer formed over the first conductive layer, wherein the interpoly dielectric layer includes a silicon oxide layer; and
a second conductive layer formed over the interpoly dielectric layer, wherein the silicon oxide layer has an oxygen to silicon (O/Si) ratio between 1.5 to 2.5.
